(19) United States
(12) Patent Application Publication
(10) Pub. No.: US 2006/0017060 A1
(43) Pub. Date: Jan. 26, 2006

(54) Vertical conducting nitride diode using an electrically conductive substrate with a metal connection

(75) Inventors: Nai-Chuan Chen, Tao-Yuan (TW); Pen-Hsiu Chang, Taipei City 116 (TW); An-Ping Chiu, Tao-Yuan (TW); Chuan-Feng Shih, Jhonghe City (TW); Shun-Da Teng, Beinan Township (TW)

Correspondence Address: NIKOLAI & MERSEREAU, P.A., 900 SECOND AVENUE SOUTH, SUITE 820, MINNEAPOLIS, MN, 55402, US

(73) Assignees: Nai-Chuan Chen, Tao-Yuan (TW); Uni Light Technology Inc., Taoyuan Hsien (TW)

(21) Appl. No.: 10/899,703

(22) Filed: Jul. 26, 2004

(51) Int. Cl. H01L 33/00

(52) U.S. Cl. 257/99; 257/103

(57) ABSTRACT

A semiconductor device using an electrically conductive substrate that has a metal connection includes an n-type/p-type electrically conductive substrate and one buffer layer formed on the n-type/p-type electrically conductive substrate. An electrically conductive semiconductor layer is formed on the buffer layer, and the metal connection is formed between the electrically conductive semiconductor layer and the electrically conductive substrate, wherein the electrically conductive semiconductor layer is an n-type/p-type nitride.

### BACKGROUND OF THE INVENTION

1. Field of the Invention

The present invention relates to a vertically conducting nitride diode using an electrically conductive substrate, and more particularly to a nitride diode with one of the nitride layer is connected to the conductive substrate by metal.

2. Description of Related Art

It is known that the nitride semiconductor has an tunable energy band gap ranging from 0.7 eV to 6.1 eV via modulating the ratio of Al, Ga and In in the AlGaInN. This character makes the nitride semiconductor possible used in the applications of light emitting devices from the infrared to the ultraviolet. However, there is no suitable substrate which is lattice matched to the nitride semiconductor. Therefore, the fabrication of nitride device was difficult until a high-quality nitride thin film had been successfully grown on a sapphire (Al₂O₃) substrate. Recently, the applications including UV, blue, green, and white light emitting diodes (LEDs), blue laser diode, the light source of panel and keypads of cell phone, TV wall, and traffic signals are all based on the nitride semiconductor.

Although the nitride material is widely used today, the substrate for the nitride epitaxy is hardly changed. Most of the nitride products are grown on sapphire. Therefore, some disadvantages are followed, including,

1. The sapphire substrate is expensive.

2. The sapphire substrate usually has a small area about two inches diameter. As to the small area, the manufacturing cost for each device is high.

3. The sapphire is an insulate material. Consequently, the electrodes of the device have a horizontal structure, that is, the p-electrode and the n-electrode are located on the same side when a LED is made on sapphire. As a result, the chip process of forming a device becomes complicated and the throughput is hindered. When packaging, the cost of wire bonding is also higher than the one with vertical electrode structure.

4. The heat dissipating ability of the sapphire is not good such that the scope of application for the nitride device grown on sapphire is limited, especially to a high power device.

Except sapphire, some marketed products use silicon carbide (SiC) as their substrate. To compare the SiC with the sapphire, the SiC has two advantages as follow.

1. The SiC is electrically conductive such that the SiC can be used as a substrate for a vertical conducting device.

2. The SiC has a high thermal conductivity.

However, the SiC has a crucial disadvantage that the SiC has higher price than that of the sapphire. Consequently, many research organizations try to use silicon (Si) as a substrate for nitride epitaxy.

To use silicon (Si) as a substrate for nitride epitaxy, several advantages are followed,

1. The Si substrate is electrically conductive that can simplify the manufacturing procedure and reduce the cost of manufacture.

2. The Si substrate has a high thermal conductivity (1.5 W-cm⁻¹ being used for an element with a high power).

3. The Si substrate may have a big area. In the current technology, the Si substrate may have a diameter about 12 inches.

4. The nitride device grown on Si substrate can be easily combined to the current advanced Si technology to form opto-electronic integrated circuit.

In order to use the Si as a substrate for nitride epitaxy, it is necessary to form a buffer layer on Si first. With reference to FIG. 1, a structure of light emitting diode, for example, can be grown on a Si substrate. Currently, the most effective buffer layer is aluminum nitride (AlN) or AlGaN. However, the AlN is an insulator and the properties of the AlGaN is set between a semiconductor and an insulator corresponding to the composition thereof such that a series resistance between the lower structure (such as a GaN film) and the Si substrate is raised.

The present invention has arisen to mitigate and/or obviate the disadvantages by metal connection between a nitride semiconnector and an electrically conductive substrate.

### SUMMARY OF THE INVENTION

The main objective of the present invention is to form a vertically conducting nitride diode using an electrically conductive substrate, and more particularly to a nitride diode with one of the nitride layer is connected to the conductive substrate by metal.

To achieve the objective, the device in accordance with the present invention comprises an n-type/p-type electrically conductive substrate and one buffer layer formed on the n-type/p-type electrically conductive substrate. At least an electrically conductive nitride layer is formed on the buffer layer, and the metal connection is formed between the electrically conductive nitride layer and the electrically conductive substrate, wherein the electrically conductive nitride layer is an n-type/p-type nitride.

Further benefits and advantages of the present invention will become apparent after a careful reading of the detailed description with appropriate reference to the accompanying drawings.

### BRIEF DESCRIPTION OF THE DRAWINGS

FIG. 1 is a nitride LED structure grown on an electrically conductive substrate;

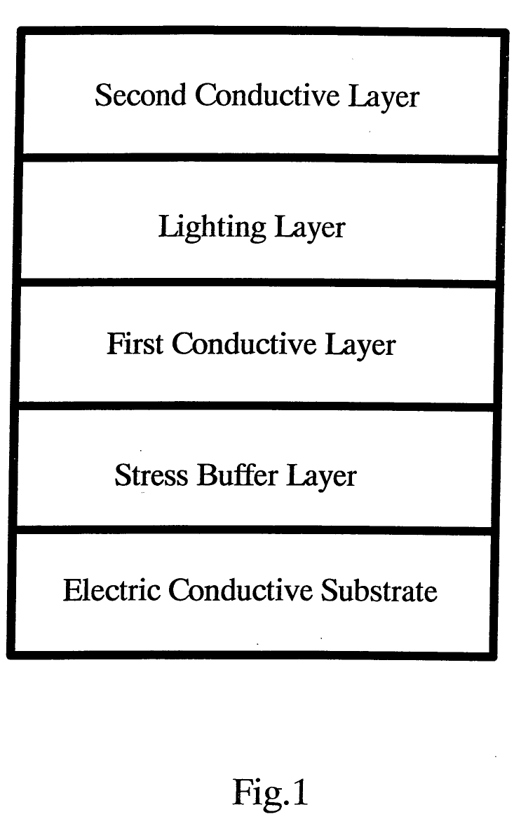

FIG. 2 is a side view of a nitride LED chip using an electrically conductive substrate that has a metal connection in accordance with the present invention;

FIG. 3 is a top view of the chip in FIG. 2;

FIG. 4 is a second embodiment of the chip using an electrically conductive substrate that has a metal connection; and

FIG. 5 is a top view of the device in FIG. 4.

### DETAILED DESCRIPTION OF THE INVENTION

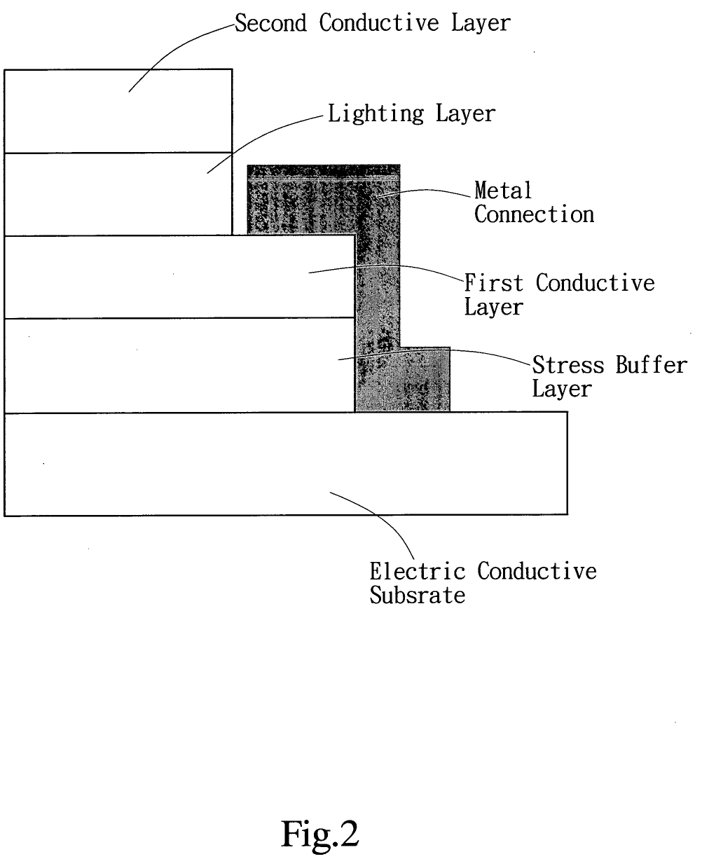

Referring to the drawings and initially to FIG. 2, a method in accordance with the present invention is provided to form a metal connection between a nitride semiconnector and an electrically conductive substrate, wherein the metal connection is an ohmic contact to the nitride semiconductor and to the substrate. The electrically conductive substrate is used for an LED, a laser or a photo-detector. The metal connection is formed by the following ways: evaporation, sputter, wire-bonding, electroplating, electrolessplating and metal fuse. The metal of the above forming ways is respectively selected from the group consisting of gold, silver, copper, platinum, palladium, zinc, nickel, titanium and chromium.

An electrically conductive substrate is previously prepared. The electrically conductive substrate is selected from the group consisting of Si substrate, SiC substrate and gallium arsenide (GaAs) substrate. A buffer layer of AlN is formed on the electrically conductive substrate in low temperature after cleaning process. The layer of AlN is used as a buffer layer. An AlGaN/GaN supper-lattice middle layer is formed on the buffer layer in high temperature. A first conductive type layer (n-type GaN layer) is formed on the middle layer and a multi-quantum-well (MQW) light emitting layer is formed on the first conductive type layer. Finally, a second conductive type layer (p-type GaN layer) is formed on the MQW and the epitaxy of LED structure is finished.

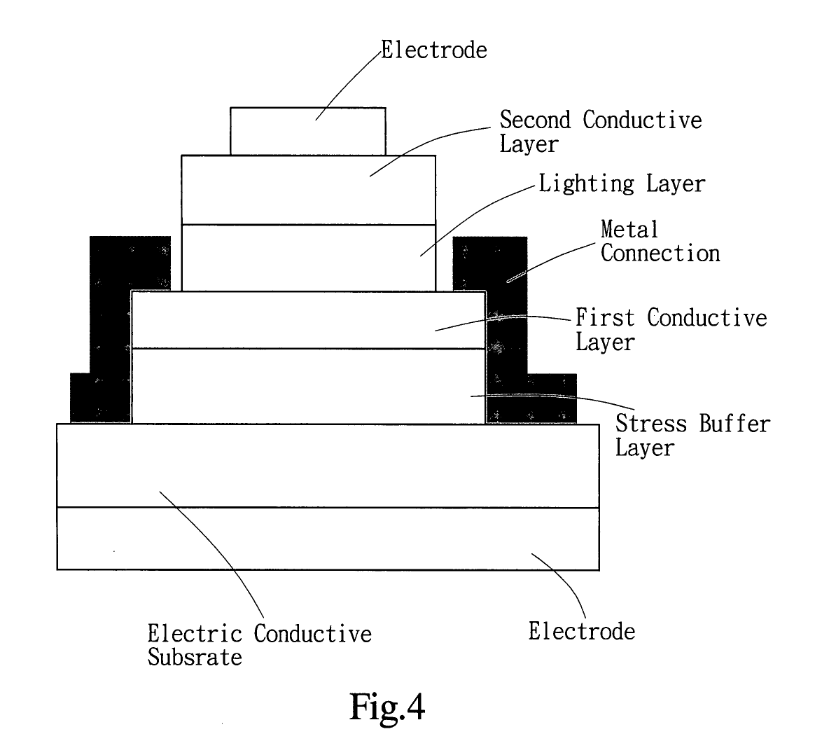

With reference to FIGS. 2 and 4, the epi-wafer is respectively partially etched to the electrically conductive substrate and the first conductive type layer. A metal connection is formed between the first conductive type layer and the electrically conductive substrate by evaporation, sputter, wire-bond electroplating or electrolessplating.

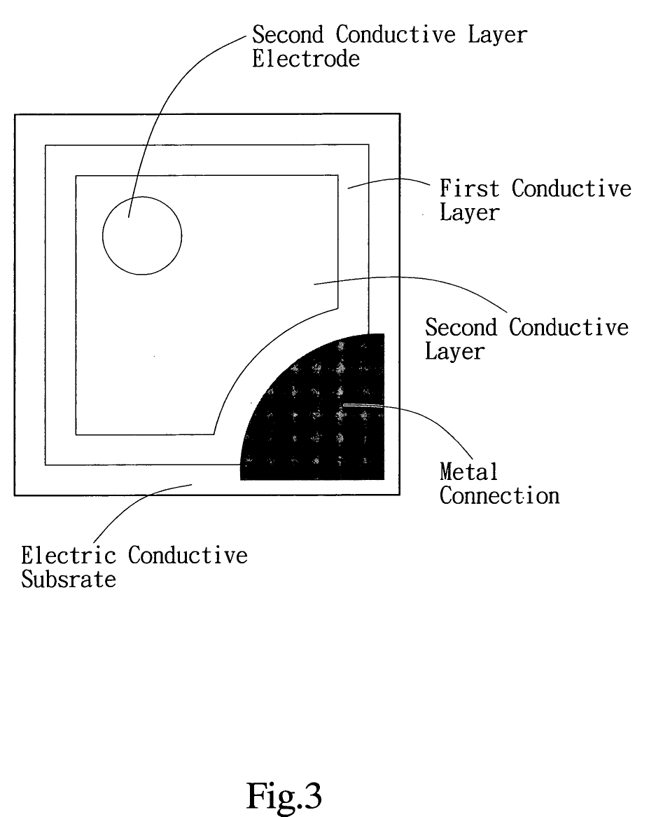

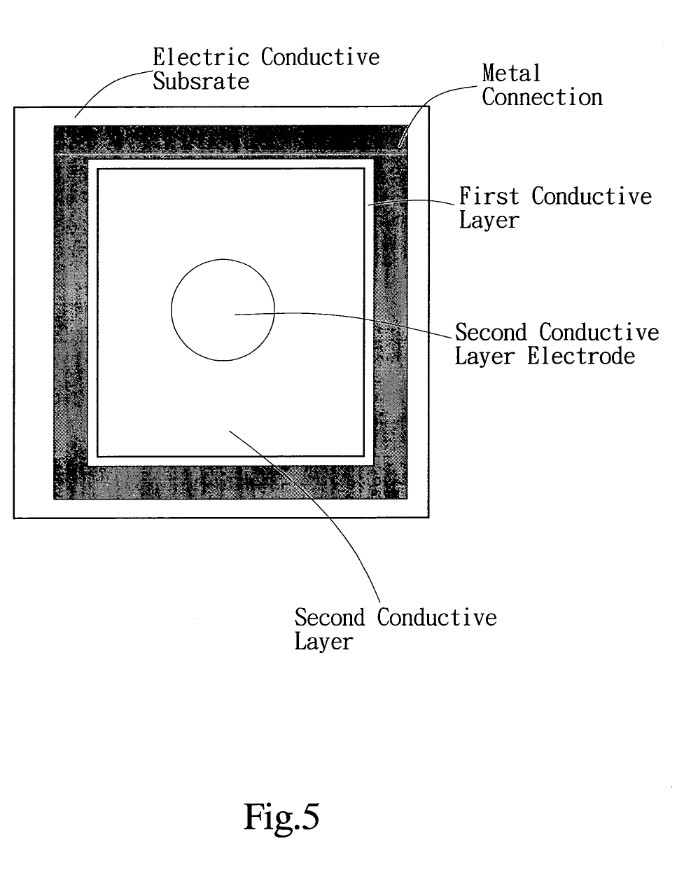

With reference to FIGS. 2 and 3, the electric current will flow from the electrically conductive substrate into the metal connection that has a small interface electric resistance, and laterally flows into the first conductive type layer (n-type GaN layer). With reference to FIGS. 4 and 5, the electrons will laterally and longitudinally flow to the first conductive type layer, and therefore eschew the high resistive buffer layer.

As described above, the metal connection between the nitride semiconductor and the electrically conductive substrate has an electric resistance that is much smaller than the buffer layer between the electrically conductive substrate and the first conductive type layer (n-type GaN layer). Consequently, the electrons will flow from the electrically conductive substrate to the nitride semiconductor via the metal connection for reducing the electric resistance between the electric conductive substrate and the first conductive type layer (n-type GaN layer). Consequently, the lifetime of the device is elongated when the series resistance is reduced and the device can be operated at a lower voltage.

Although the invention has been explained in relation to its preferred embodiment, it is to be understood that many other possible modifications and variations can be made without departing from the spirit and scope of the invention as hereinafter claimed.

What is claimed is:

1. A semiconductor device using an electrically conductive substrate that has a metal connection between the substrate and a semiconductor layer grown on it, comprising an n-type/p-type electrically conductive substrate and one buffer layer formed on the n-type/p-type electrically conductive substrate, an electrically conductive semiconductor layer formed on the buffer layer, and a metal connection formed between the electrically conductive semiconductor layer and the electrically conductive substrate, wherein the electrically conductive semiconductor layer is an n-type/p-type nitride.

2. The semiconductor device as claimed in claim 1, wherein the electrically conductive substrate is selected from the group consisting of a silicon substrate, a silicon carbide substrate and a gallium arsenide substrate.

3. The semiconductor device as claimed in claim 1 being a nitride light emitting diode.

4. The semiconductor device as claimed in claim 1 being a nitride laser diode.

5. The semiconductor device as claimed in claim 1 being a nitride photo-detector.

6. The semiconductor device as claimed in claim 1, wherein the metal connection is formed by evaporation and the metal is selected from a group consisting of gold, silver, copper, platinum, palladium, zinc, nickel, titanium and chromium.

7. The semiconductor device as claimed in claim 1, wherein the metal connection is formed by wire-bond and the metal is selected from a group consisting of gold and aluminum.

8. The semiconductor device as claimed in claim 1, wherein the metal connection is formed by sputter and the metal is selected from a group consisting of gold, silver, copper, platinum, palladium, zinc, nickel, titanium and chromium.

9. The semiconductor device as claimed in claim 1, wherein the metal connection is formed by metal fuse and the metal is selected from a group consisting of gold, silver, copper, platinum, palladium, zinc, nickel, titanium and chromium.

10. The semiconductor device as claimed in claim 1, wherein the metal connection is formed by electroplating and the metal is selected from a group consisting of gold, silver, copper, platinum, palladium, zinc, nickel, titanium and chromium.

11. The semiconductor device as claimed in claim 1, wherein the metal connection is formed by electrolessplating and the metal is selected from a group consisting of gold, silver, copper, platinum, palladium, zinc, nickel, titanium and chromium.
